(19) United States
(12) Patent Application Publication
(10) Pub. No.: US 2014/0094356 A1
(43) Pub. Date: Apr. 3, 2014

(54) TREATMENT PROCESS, OXIDE-FORMING TREATMENT COMPOSITION, AND TREATED COMPONENT

(71) Applicant: GENERAL ELECTRIC COMPANY, Schenectady, NY (US)

(72) Inventors: Yuk-Chiu LAU, Ballston Lake, NY (US); Vinod Kumar PAREEK, Albany, NY (US); Joshua L. MARGOLIES, Niskayuna, NY (US); Raymond Grant ROWE, Niskayuna, NY (US)

(73) Assignee: GENERAL ELECTRIC COMPANY, Schenectady, NY (US)

(21) Appl. No.: 13/630,584

(22) Filed: Sep. 28, 2012

(51) Int. Cl. B05D 7/00; C04B 35/04; C23F 11/18; C04B 35/01; B05D 3/02; C23C 16/40

(52) U.S. Cl. 501/108; 427/372.2; 427/248.1; 427/140; 252/387; 501/94

(57) ABSTRACT

A treatment process, an oxide-forming treatment composition, and a treated component are disclosed. The treatment process includes applying an oxide-forming treatment composition to a ceramic coating and heating the oxide-forming treatment composition to form an oxide within the ceramic coating. The oxide-forming treatment composition includes a solute and a corrosion inhibitor. The oxide-forming treatment composition is super-saturated with the corrosion inhibitor. The treated component includes a ceramic coating and one or both of a corrosion inhibitor and an oxide formed by an oxide-forming treatment composition having the corrosion inhibitor. The corrosion inhibitor and the oxide-forming treatment composition are within the ceramic coating.

### FIELD OF THE INVENTION

The present invention is directed to manufactured components and treating of manufactured components. More specifically, the present invention is directed to treatment processes, treatments, and treated components for resisting corrosive attack.

### BACKGROUND OF THE INVENTION

Modern high-efficiency combustion turbines have firing temperatures that exceed about 2000° F. (1093° C.), and firing temperatures continue to increase as demand for more efficient engines continues. Many components that form the combustor and “hot gas path” turbine sections are directly exposed to aggressive hot combustion gases, for example, the combustor liner, the transition duct between the combustion and turbine sections, and the turbine stationary vanes and rotating blades and surrounding ring segments. In addition to thermal stresses, these and other components are also exposed to mechanical stresses and loads that further wear on the components.

Many of the cobalt-based and nickel-based superalloy materials traditionally used to fabricate the majority of combustion turbine components used in the hot gas path section of the combustion turbine engine are insulated from the hot gas flow by coating the components with a thermal barrier or metallic overlay coating in order to survive long-term operation in this aggressive high-temperature combustion environment.

Thermal barrier coating systems often consist of four layers: the metal substrate, metallic bond coat, thermally grown oxide, and ceramic topcoat. The ceramic topcoat is typically composed of yttria-stabilized zirconia (YSZ), which is desirable for having very low thermal conductivity while remaining stable at nominal operating temperatures typically seen in applications. Such ceramic topcoats can be expensive to apply and/or limited in application methodology.

YSZ is a well known material used to improve the performance of metals used in high temperature applications. The YSZ is applied, typically by a high temperature thermal spray coating process. The YSZ increases the operating temperature of the high temperature substrate metal. In addition, a bond coat is applied between the YSZ and the high temperature metal reducing the thermal expansion mismatch between the YSZ and the high temperature metal, which improves the spallation resistance.

Gas turbine engines can be operated using a number of different fuels. These fuels are combusted in the combustor section of the engine at temperatures at or in excess of 2000° F. (1093° C.), and the gases of combustion are used to rotate the turbine section of the engine, located aft of the combustor section of the engine. Power is generated by the rotating turbine section as energy is extracted from the hot gases of combustion. It is generally economically beneficial to operate the gas turbine engines using the most inexpensive fuel available. One of the more abundant and inexpensive petroleum fuels is heavy fuel oil (HFO). One of the reasons that HFO is an economical fuel is that it is not heavily refined. Not being heavily refined, it contains a number of impurities. One of these impurities is vanadium, which forms vanadium oxide (V₂O₅) at the high temperatures of combustion. Even though MgO is added as a fuel additive and acts as an inhibitor for reaction of vanadium species that forms an inert magnesium vanadate compound on or near the outer surface of the thermal barrier coating, MgO does not completely prevent the attack of YSZ thermal barrier coatings, as vanadium oxide can penetrate microcracks and porosity in the thermal barrier coatings, providing access not only to the YSZ thermal barrier coating, but also the underlying bond coat. V₂O₅ is an acidic oxide that can leach yttria from YSZ in cracks and porosity that occur in such thermal barrier coatings. The mechanism of attack is provided by the following reaction:

ZrO₂(Y₂O₃)+V₂O₅→ZrO₂ (monoclinic)+2YVO₄

Thus, V₂O₅ maintains the ability to rapidly attack YSZ, causing it to deteriorate and be removed by the hot gas stream. The loss of the TBC exposes the substrate metal and any remaining bond coat to the hot gases of combustion at elevated temperatures. At these elevated temperatures, the substrate metal and the bond coat are subject to corrosion from the hot gases of combustion, which shorten their life. As a result, the components, such as combustors and turbine blades, must be replaced in shorter intervals, which also means additional maintenance time for the turbine during which time it is not producing power. Due to such drawbacks, HFO has been used in steam boilers having inexpensive components that can be discarded regularly.

The drawbacks of using HFO can be partially overcome by modifying the composition of the ceramic coating in a gas turbine. For example, gadolinium zirconate can be used instead of YSZ. Although such ceramic coatings resist corrosive attack from calcium-magnesium-aluminosilicate (CMAS), they do not resist corrosive attack from vanadium. In addition, use of gadolinium zirconate alters physical properties in comparison to use of YSZ.

Corrosive attack from vanadium can initially be reduced or eliminated by adding additional layers to a coating system. For example, adding an impermeable barrier layer to YSZ can initially reduce or eliminate corrosive attack from vanadium in HFO. Likewise, laser glazing a top surface of YSZ to form a seal can initially reduce or eliminate corrosive attack from vanadium in HFO. However, such additional layers can increase cracking tendency upon thermal expansion/contraction associated with operation of a gas turbine. This cracking can compromise the additional layer, the YSZ, and/or other layers within the coating system, thereby leading to corrosive attack.

A treatment process, an oxide-forming treatment composition, and a treated component that do not suffer from one or more of the above drawbacks would be desirable in the art.

### BRIEF DESCRIPTION OF THE INVENTION

In an exemplary embodiment, a treatment process includes applying an oxide-forming treatment composition to a ceramic coating and heating the oxide-forming treatment composition to form an oxide within the ceramic coating. The oxide-forming treatment composition includes a solute and a corrosion inhibitor.

In another exemplary embodiment, an oxide-forming treatment composition includes a solute and a corrosion inhibitor. The oxide-forming treatment composition is super-saturated with the corrosion inhibitor.

In another exemplary embodiment, a treated component includes a ceramic coating and one or both of a corrosion inhibitor and an oxide formed by an oxide-forming treatment composition having the corrosion inhibitor. The corrosion inhibitor and the oxide-forming treatment composition are within the ceramic coating.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 is a schematic view of an exemplary component treated by an exemplary treatment process according to the disclosure.

FIG. 2 is a schematic view of an exemplary treatment process according to the disclosure.

Wherever possible, the same reference numbers will be used throughout the drawings to represent the same parts.

### DETAILED DESCRIPTION OF THE INVENTION

Provided is an exemplary treatment process, oxide-forming treatment composition, and treated component that do not suffer from one or more of the above drawbacks. Embodiments of the present disclosure reduce or eliminate leaching of ceramic coating constituents (for example, from vanadium compounds), reduce or eliminate corrosive effect of combusting heavy fuel oils in gas turbines, permit use of higher firing temperatures in gas turbines thereby permitting higher efficiency, extend the usable life of hot gas path components in gas turbines, protect coatings system layers (for example, metal substrates, metallic bond coat, thermally grown oxide, ceramic topcoats, and combinations thereof), expand the usefulness of yttria-stabilized zirconia (YSZ) coatings, increase thermal expansion/contraction resistance, or combinations thereof

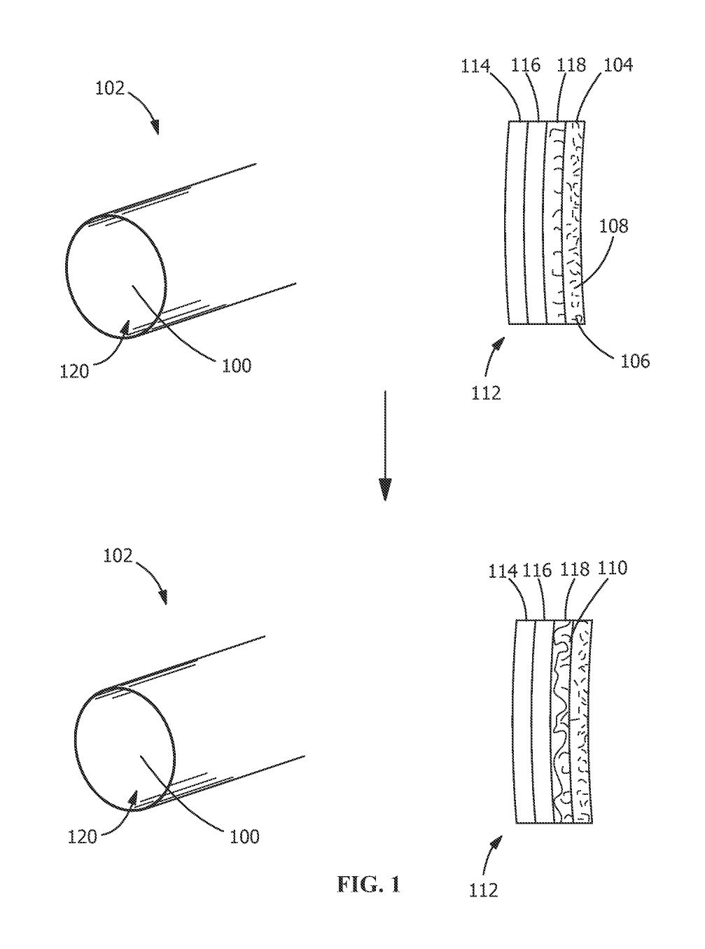

FIG. 1 shows a component 102 with a coating 100. The coating 100 is positioned on any suitable portion of the component 102. In one embodiment, the coating 100 is on an interior portion 120 of the component 102, such as along a hot gas path. In other embodiments, the coating 100 is on portions of the component 102 that are not interior portions or are not within a hot gas path. The component 102 is any suitable component. For example, in one embodiment, the component 102 is a combustor. In a further embodiment, the component 102 is a liner for a combustor of a gas turbine. In other embodiments, the component 102 is a stationary or rotating air foil or a shroud (for example, a stationary shroud).

The coating 100 is any suitable coating. In one embodiment, the coating 100 includes a substrate 114, a metallic coating such as a MCrAlY coating 116, and a ceramic layer 118. As used herein, the term “MCrAlY” refers to a composition having chromium, aluminum, yttrium, and M, where M is a metal or alloy selected from the group consisting of nickel metal, iron metal, cobalt metal, and combinations thereof. In one embodiment, the substrate 114 is an alloy containing iron, nickel, cobalt, titanium, and other suitable components. In one embodiment, the substrate 114 has a composition, by weight, about 0.1% C, about 22% Cr, about 9% Mo, about 0.5% W, about 1% Co, about 19% Fe, and a balance Ni. In one embodiment, the substrate 114 has a composition, by weight, of between about 0.15% and about 0.19% C, between about 13.7% and about 14.3% Cr, between about 9.0% and 10.0% Co, between about 4.8 and about 5.2% Ti, between about 2.8% and about 3.2% Al, about between about 3.7% and about 4.3% W, between about 3.7% and 4.3% Mo, at least about 7.7% W & Mo, and a balance Ni. In one embodiment, the substrate 114 has a composition, by weight, of between about 50% and about 55% Ni, between about 17% and about 21% Cr, between about 4.7% and about 5.5% Nb/Ta, between about 2.8% and about 3.3% Mo, between about 0.65% and about 1.2% Ti, between about 0.20% and about 0.80% Al, up to about 1.0% Co, up to about 0.08% C, up to about 0.35% Mn, up to about 0.35% Si, up to about 0.015% P, up to about 0.015% S, up to about 0.006% Bo, up to about 0.30% Cu, and a balance Fe.

The MCrAlY coating 116 protects the substrate 114 from high temperatures, such as in a hot gas path of the component 102. In one embodiment, the MCrAlY coating 116 is a metal or alloy selected from the group consisting of a platinum metal, an iridium metal, an iridium-hafnium metal, an iridium-platinum metal, a platinum-rhenium metal, a platinum-based alloy, iridium-based alloy, an iridium-hafnium-based alloy, an iridium-platinum-based alloy, a platinum-rhenium-based alloy, and combinations thereof. In one embodiment, the MCrAlY coating 116 has a thickness of about 2 mils, about 4 mils, about 6 mils, about 10 mils, about 15 mils, between about 2 mils and about 4 mils, between about 4 mils and about 6 mils, between about 6 mils and about 10 mils, between about 10 mils and about 15 mils, or any suitable combination, sub-combination, range, or sub-range within.

The ceramic layer 118 is positioned on the MCrAlY coating 116. In one embodiment, the ceramic layer 118 includes yttria-stabilized zirconia. In one embodiment, the ceramic layer 118 has a thickness of about 1 mil, about 2 mils, about 3 mils, about 4 mils, about 5 mils, between about 1 mil and about 2 mils, between about 1 mil and about 3 mils, between about 1 mil and about 5 mils, between about 2 mils and about 3 mils, between about 3 mils and about 4 mils, between about 20 mils and about 40 mils (for example, as in combustor and stationary shrouds), greater than about 40 mils, between about 5 mils and about 20 mils (for example, as in air foils), or any suitable combination, sub-combination, range, or sub-range within.

An oxide-forming treatment composition 104 is on and/or within the coating 100. The oxide-forming treatment composition 104 includes a solute 106 and a corrosion inhibitor selected from the group consisting of magnesium nitrate hexahydrate, magnesium oxide, magnesium hydroxide, and combinations thereof. The oxide-forming treatment composition 104 is super-saturated with the corrosion inhibitor thereby forming crystals 108 of the corrosion inhibitor. The oxide-forming treatment composition 207 is a solution (for example, in water), a colloidal suspension, a gel, a sol, a vapor, or a combination thereof.

In one embodiment, the oxide-forming treatment composition 104 penetrates portions of the ceramic layer 118 and/or the MCrAlY coating 116. For example, in one embodiment, the oxide-forming treatment composition 104 penetrates cracks, pores, asperities, machined features, delaminations, or combinations thereof. The oxide-forming treatment composition 104 is resistant to corrosion. In one embodiment, the oxide-forming treatment composition is resistant to corrosive attack from sulfur compounds, sodium compounds, phosphorus compounds, vanadium compounds, or combinations thereof.

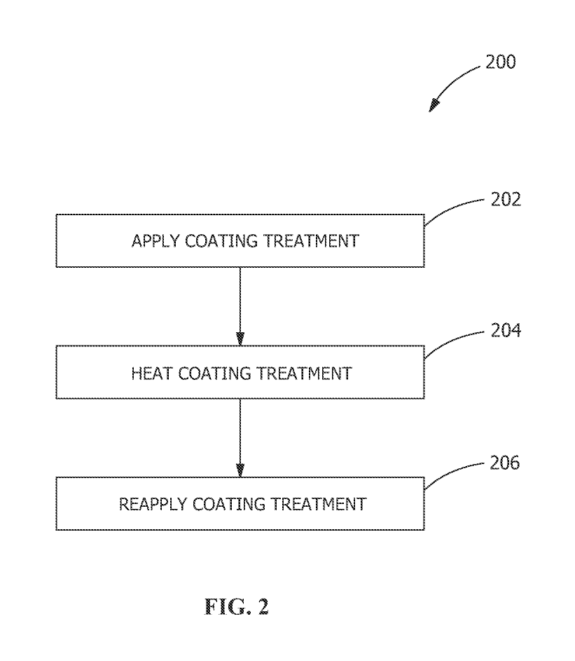

Referring to FIG. 2, in one embodiment, a treatment process 200 includes applying the oxide-forming treatment composition 104 (step 202), heating the oxide-forming treatment composition 104 (step 204), and optionally reapplying the oxide-forming treatment composition 104 (step 206). Upon applying the oxide-forming treatment composition 104 (step 202) and heating the oxide-forming treatment composition 104 (step 204), an oxide 110 is formed within the coating 100, thereby forming a treated component 112.

In one embodiment, the oxide-forming treatment composition 104 is applied (step 202) by a technique selected from the group consisting of brushing, injecting, condensing, dipping, spraying (for example, aerosol spraying), and combinations thereof. In one embodiment, the oxide-forming treatment composition is applied at a suitable application temperature. Suitable application temperatures, for example for brushing, injecting, dipping, and/or spraying, are between about 32° F. and about 212° F. between about 40° F. and about 120° F., between about 60° F. and about 100° F., between about 70° F. and about 80° F., at about 70° F., at about 75° F., or any suitable combination, sub-combination, range, or sub-range within). Suitable application temperatures, for example for condensing, are greater than about 212° F.

In one embodiment, the oxide-forming treatment composition 104 is heated (step 204) to a heating temperature (for example, between about 800° F. and about 1200° F., between about 800° F. and about 1000° F., between about 1000° F. and about 1200° F., between about 900° F. and about 1100° F., at about 900° F., at about 1000° F., at about 1100° F., or any suitable combination, sub-combination, range, or sub-range within). In one embodiment, the heating is for a heating period, for example, between about 10 minutes and about 20 minutes, between about 10 minutes and about 15 minutes, between about 15 minutes and about 20 minutes, about 10 minutes, about 15 minutes, about 20 minutes, or any suitable combination, sub-combination, range, or sub-range within. In one embodiment, a lower temperature (for example, less than about 800° F.) is used with a longer duration of the heating (for example, one or two days).

In one embodiment, the oxide-forming treatment composition 104 is heated (step 204) by an external heating source, for example, electrically-heated air, an infrared lamp, a quartz lamp, a flame, a thermal spray torch, or any other suitable heating mechanism. In one embodiment, the oxide-forming treatment composition 104 is heated (step 204) by the component 102 being positioned in or is a portion of a gas turbine (not shown) and the gas turbine being operated.

In one embodiment, the oxide-forming treatment composition 104 is reapplied (step 206), for example, after use/operation of the component 102. In one embodiment, with the component 102 being positioned in or is a portion of a gas turbine, the oxide-forming treatment composition 104 is reapplied (step 206) periodically over the life of the component 102.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A treatment process, comprising:
applying an oxide-forming treatment composition to a ceramic coating; and
heating the oxide-forming treatment composition to form an oxide within the ceramic coating;
wherein the oxide-forming treatment composition includes a solute and a corrosion inhibitor.

2. The treatment process of claim 1, wherein the corrosion inhibitor is selected from the group consisting of magnesium nitrate hexahydrate, magnesium oxide, magnesium hydroxide, and combinations thereof.

3. The treatment process of claim 1, wherein the oxide-forming treatment composition is super-saturated with the corrosion inhibitor.

4. The treatment process of claim 1, wherein the oxide-forming treatment composition is capable of forming crystals.

5. The treatment process of claim 1, wherein the oxide is magnesium oxide.

6. The treatment process of claim 1, wherein the oxide formed within the ceramic coating penetrates into regions selected from the group consisting of cracks, pores, asperities, machined features, delaminations, and combinations thereof.

7. The treatment process of claim 1, wherein the oxide-forming treatment composition is a colloidal suspension or a gel.

8. The treatment process of claim 1, wherein the oxide-forming treatment composition is a vapor.

9. The treatment process of claim 1, wherein the oxide-forming treatment composition is applied by a technique selected from the group consisting of brushing, dipping, injecting, condensing, spraying, and combinations thereof.

10. The treatment process of claim 1, wherein the heating of the oxide-forming treatment composition is to a heating temperature of between about 800° F. and about 1200° F.

11. The treatment process of claim 1, wherein the heating is for a heating period of between about 10 minutes and about 20 minutes.

12. The treatment process of claim 1, wherein the heating is for a heating period of greater than 1 day.

13. The treatment process of claim 1, wherein the ceramic coating is within a hot-gas path of a gas turbine.

14. The treatment process of claim 13, further comprising operating the gas turbine then reapplying the oxide-forming treatment composition.

15. The treatment process of claim 13, further comprising operating the gas turbine with a heavy fuel oil.

16. An oxide-forming treatment composition, comprising:
a solute; and
a corrosion inhibitor;
wherein the oxide-forming treatment composition is super-saturated with the corrosion inhibitor.

17. The oxide-forming treatment composition of claim 16, wherein the corrosion inhibitor is selected from the group consisting of magnesium nitrate hexahydrate, magnesium oxide, magnesium hydroxide, and combinations thereof.

18. A treated component, comprising:
a ceramic coating;
one or both of a corrosion inhibitor and an oxide formed by an oxide-forming treatment composition having the corrosion inhibitor;
wherein the corrosion inhibitor and the oxide-forming treatment composition are within the ceramic coating.

19. The treated component of claim 18, wherein the ceramic coating is within a hot-gas path of a gas turbine.

20. The treated component of claim 18, wherein the oxide is selected from the group consisting of magnesium oxide, magnesium oxide, magnesium hydroxide, and combinations thereof.
